(19) United States
(12) Patent Application Publication
(10) Pub. No.: US 2009/0091245 A1
(43) Pub. Date: Apr. 9, 2009

(54) Method for manufacturing an oled, an intermediate product for manufacturing an oled, as well as an oled

(75) Inventors: Franciscus Cornelius Dings, Veldhoven (NL); Remco Leonardus Johannes Robertus Pennings, Nuenen (NL)

Correspondence Address: BIRCH STEWART KOLASCH & BIRCH, PO BOX 747, FALLS CHURCH, VA, 22040-0747, US

(73) Assignee: OTB Group B.V., Eindhoven (NL)

(21) Appl. No.: 11/919,747

(22) PCT Filed: May 4, 2005
(86) PCT No.: PCT/NL2005/000340

§ 371 Date: Feb. 21, 2008

(51) Int. Cl. H01J 1/62; H01L 21/02

(52) U.S. Cl. 313/504; 438/22; 257/E21.002

(57) ABSTRACT

Method for manufacturing a light emitting device, the light emitting device having a light emitting area, the method comprising at least the following steps: —providing a substrate; —providing at least one first electrode on the substrate; —forming first contacts which are connected to the at least one first electrode; —forming second contacts which are arranged for contacting at least one second electrode; —forming a conductive interconnection between the first and the second contacts before the at least one second electrode is formed; —after having applied the conductive layer for forming the at least one second electrode on the substrate removing the conductive interconnection between the first and second contacts.

The invention relates to a method for manufacturing an organic light emitting device.

The invention also relates to an intermediate product for forming therefrom an organic light emitting device.

Because light emitting devices, more specifically to organic light emitting devices hereafter referred to as OLED's, are mostly manufactured in an extremely dry and clean environment static electric charges can built up on the device during the manufacturing process. After first electrodes, the hole injection layer and the light emitting material have been applied on the substrate, a conductive layer is applied for forming second electrodes. During application of this conductive layer, the static electric charges present on the device can suddenly discharge. As a consequence, the light emitting area or parts of the light emitting area, e.g. some of the pixels, on the device may be damaged and loose their capability of emitting light and the device is lost.

It is an object of the invention to solve this problem.

To that end, the invention provides a method for manufacturing a light emitting device, the light emitting device having a light emitting area, the method comprising at least the following steps:

providing a substrate;

providing at least one first electrode on the substrate;

forming first contacts which are connected to the at least one first electrode;

forming second contacts which are arranged for contacting at least one second electrode;

forming a conductive interconnection between the first and the second contacts before the at least one second electrode is formed;

after having applied the conductive layer for forming the at least one second electrode on the substrate removing the conductive interconnection between the first and second contacts.

The invention also provides an intermediate product for forming therefrom a light emitting device, the intermediate product comprising:

a substrate;

at least one first electrodes;

first contacts connected to the at least one first electrodes;

second contacts arranged for connection to at least one second electrode; and

a conductive interconnection between the first and second contacts.

The first electrodes can be the anode and the second electrodes can be the cathode or vice versa. The first and second electrodes can, e.g., be crossing anode and cathode lines. When the layer for forming the at least one second electrodes is applied, the at least one second electrodes is immediately conductively interconnected with the at least one first electrodes via the conductive interconnection between the first and second contacts. In view thereof, any static charge on the device can flow to the second conductors via this interconnection and does not have to flow via the light emitting material which is arranged between the first and second electrodes. Consequently, the light emitting area will not be damaged during formation of the at least one second electrode as a consequence of static electrical discharge.

From a process efficiency point it is, according to a further elaboration of the invention, advantageous when the conductive interconnection is made in a process step which is already present for formation of another part of the OLED. This could be e.g. a process step in which the first and/or second contacts are formed.

According to a further elaboration of the invention it is advantageous when the conductive interconnection is formed from a material which is conductive but has a considerable resistance so that, when the first and second electrodes are connected to a electrical source the associated light emitting area will light up and can be tested. This is advantageous because it is preferred to test the light emitting properties of the LED's or OLED's when these are still part of the substrate. Normally, a substrate will contain a plurality of intermediate products from which OLED's are to be formed. These intermediate products are, in fact, ready to become an OLED by separating them out of the substrate. However, from a process point of view, e.g. handling and the like, it is advantageous when the testing of the OLED's is done before the substrate is divided into individual OLED's. When the conductive material has a considerable resistance, as is the case in this embodiment of the invention, the OLED's can be tested when sufficient power is connected to the first and second contacts.

According to a further elaboration of the invention, the conductive interconnection is formed from the same material as the material of a hole injection layer (HIL). The material can be PEDT. Of course, this interconnection is preferably formed at the same time when the hole injection layer is applied. PEDT has the property of considerable resistance so that, when the first and second electrodes are connected to an electrical source the respective pixels will light up and can be tested.

In order to make the removal of the conductive interconnection easy, the conductive interconnection can be formed in an area which is removed by a separation operation for removing the interconnection between the first and second contacts.

From a process efficiency point of view it is advantageous when the separation operation also serves for separating out an individual OLED from the substrate.

The area in which the interconnection is formed can be a linear area extending between a first and a second contact line, the first contact line being connected to the first electrode and the second contact line being connected to the second electrode.

The contact lines may be connected to a respective contact pad for testing purposes. When the OLED's have to be tested, preferably before they are separated out from the substrate, the electrical source can be connected to the contact pads.

The invention also relates to a light emitting device, more specifically to an organic light emitting device, formed from an intermediate product according to the invention using the method according to the invention.

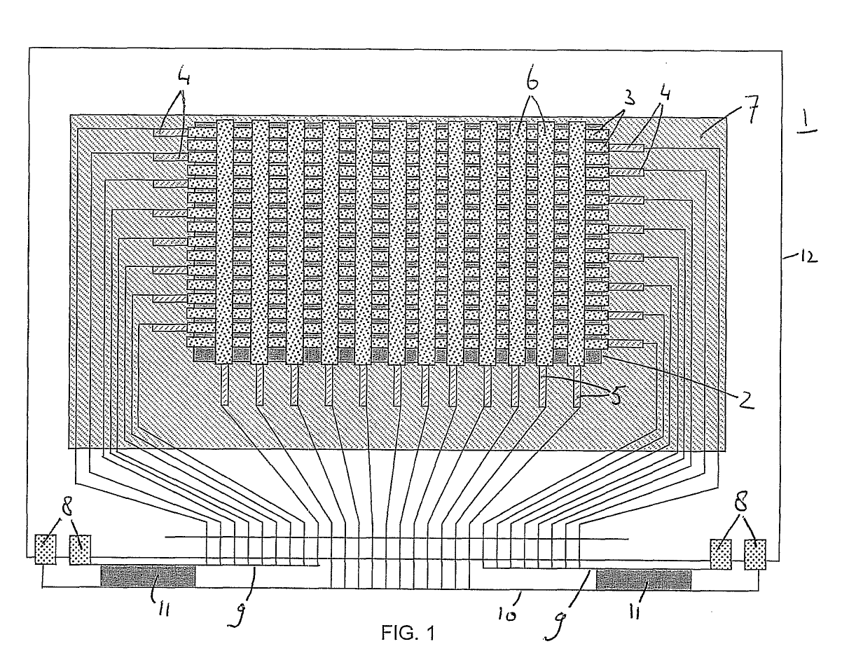

FIG. 1 shows a top plan view of an embodiment of an intermediate product from which an organic light emitting device can be formed. The intermediate product comprises a substrate 1 from e.g. glass, transparent plastic or the like. In a light emitting area 2, a first electrode in the form of first conductive lines 3, e.g. anode lines, extend in a first direction. The first electrode lines 3 are preferably made of transparent conductive oxide such as ITO. The first electrode lines 3 are connected to first contacts 4. Second contacts 5 are arranged for connection to second electrode lines 6, e.g. cathode lines. Also shown is a bank structure 7 in which pixel compartments are present. Normally, the bank structure 7 is formed from a photoresist layer. In the light emitting area 2 cathode separators (not shown) can be provided on the bank structure 6. These cathode separators are known in the art and provide a shadow structure in order to be able to apply mutually separated second electrode lines 5 with a full surface coating technique. However, second electrode lines might be formed by other techniques, e.g. inkjet printing techniques. The pixel compartments are filled, e.g. by an inkjet printing technique, with a hole injection layer (HIL) such as PEDT and with a light emitting material (LEP) such as PPV. Other materials for the hole injection layer and the light emitting material can be used and are known in the art. After applying the HIL and the LEP the second electrode lines 6 are applied.

Subsequently, the light emitting properties of the intermediate products can be tested by connecting an electrical source to the first contacts 4 and the second contacts 5. For that purpose contact pads 8 are provided which are connected via first and second contact lines 9, 10 to the first contacts 4 and the second contacts 5.

When applying the second electrode lines 6 a discharge of a static electric charge might occur through the pixels which are just formed. In order to solve that problem, the present embodiment is provided with a conductive interconnection 11 between the first and second contacts 4, respectively 5. In the present embodiment the conductive interconnection 11 is formed from the same material as the hole injection layer, i.e. in this embodiment by PEDT. In order to confine the area in which the interconnection 11 is formed, a bank structure comprising an interconnection compartment may be present in that area. In the present embodiment two conductive interconnection areas 11 are present. The interconnections 11 are linear areas extending between the first contact lines 9 and the second contact line 10. PEDT has a relatively high resistance so that it is possible to test the light emitting properties of intermediate product even when the interconnection 11 is present. Before or after testing an encapsulation system may be provided on the thus formed structure in order to protect the active layers from oxygen, moisture and the like. The encapsulation system can by a layer system or a mechanical cap in which getter material can be provided.

In order to remove the interconnection 11 between the first and the second contacts 4, respectively 5, a separation operation is performed by means of which the interconnection 11 is separated from the substrate part on which the light emitting area 2 is provided. The same separation operation serves in the present embodiment also for separating out of the substrate 1 individual OLED's. The separation operation can be a cutting operation along line 12.

The invention is not limited to the above described embodiment and various modifications are possible within the scope of the invention as defined by the claims. Indeed the intermediate product and the LED or OLED obtained therefrom may comprise additional layers or components which are not described herein because these are not relevant for the present invention. In stead of a passive OLED as described in the above embodiment example, the invention is also applicable for an active OLED. Displays for lighting and signalling having large anode and cathode electrodes are also included. In stead of electrode lines, also electrode surfaces covering a larger area of the substrate are possible.

1. Method for manufacturing a light emitting device, the light emitting device having a light emitting area, the method comprising at least the following steps: providing a substrate; providing at least one first electrode on the substrate; forming first contacts which are connected to the at least one first electrode; forming second contacts which are arranged for contacting at least one second electrode; forming a conductive interconnection between the first and the second contacts before the at least one second electrode is formed; after having applied the conductive layer for forming the at least one second electrode on the substrate removing the conductive interconnection between the first and second contacts.

2. Method according to claim 1, wherein the conductive interconnection is formed in a process step which is already present for formation of a part of the LED.

3. Method according to claim 1, wherein the conductive interconnection is formed from a material which is conductive but has a considerable resistance so that, when the at least one first electrode and the at least one second electrode are connected to an electrical source the associated light emitting area will light up and can be tested.

4. Method according to claim 1, wherein the conductive interconnection is formed from the same material as the material of a hole injection layer.

5. Method according to claim 1, wherein the conductive interconnection is formed from PEDT.

6. Method according to claim 1 wherein the conductive interconnection is formed in an area which is removed by a separation operation for removing the interconnection between the first and second contacts.

7. Method according to claim 6, wherein the separation operation also serves for separating out an individual LED from the substrate.

8. Method according to claim 1, wherein the area in which the interconnection is formed is a linear area extending between a first and a second contact line, the first contact line being connected to the at least one first electrode and the at least one second contact line being connected to the at least one second electrode.

9. Method according to claim 8, wherein the contact lines each are connected to a respective contact pad for testing purposes.

10. Intermediate product for forming therefrom an organic light emitting device, the intermediate product comprising: a substrate; at least one first electrode; first contacts connected to the first electrode; second contacts arranged for connection to at least one second electrode; and a conductive interconnection between the first and second contacts.

11. Intermediate product according to claim 10, wherein the conductive interconnection is formed from a material which is conductive but has a considerable resistance so that, when the at least one second electrode is present and when the first and second electrodes are connected to an electrical source, the associated light emitting area will light up and can be tested.

12. Intermediate product according to claim 10, wherein the conductive interconnection is formed from the same material as a hole injection layer which is applied in the light emitting area.

13. Intermediate product according to claim 10, wherein the conductive interconnection is formed from PEDT.

14. Intermediate product according to claim 10, wherein the conductive interconnection is removable.

15. Intermediate product according to claim 10, wherein the conductive interconnection is formed in an area which is removable by separation operation for removing the interconnection between the first and second contacts.

16. Intermediate product according to claim 15, wherein the separation operation also serves for separating out an individual OLED from the substrate.

17. Intermediate product according to claim 10, wherein the area in which the interconnection is formed is a linear area extending between a first and a second contact line, the first contact line being connected to the at least one first electrode and the second contact line being connected to the at least one second electrode.

18. Intermediate product according to claim 17, wherein the contact lines each are connected to a respective contact pad for testing purposes.

19. Organic light emitting device formed from an intermediate product according to claim 10 using the method for manufacturing a light emitting device, the light emitting device having a light emitting area, the method comprising at least the following steps: providing a substrate; providing at least one first electrode on the substrate; forming first contacts which are connected to the at least one first electrode; forming second contacts which are arranged for contacting at least one second electrode; forming a conductive interconnection between the first and the second contacts before the at least one second electrode is formed; after having applied the conductive layer for forming the at least one second electrode on the substrate removing the conductive interconnection between the first and second contacts.

20. Method according to claim 2, wherein the conductive interconnection is formed from a material which is conductive but has a considerable resistance so that, when the at least one first electrode and the at least one second electrode are connected to an electrical source the associated light emitting area will light up and can be tested.
